(19) United States
(12) Patent Application Publication
(10) Pub. No.: US 2005/0279987 A1
(43) Pub. Date: Dec. 22, 2005

(54) Nanostructure sensor device with polymer recognition layer

(76) Inventors: Alexander Star, Albany, CA (US); Jean-Christophe P. Gabriel, Pinole, CA (US); George Gruner, Los Angeles, CA (US)

Correspondence Address: BRIAN M. BERLINER;O'MELVENY & MYERS LLP, 400 SOUTH HOPE STREET, LOS ANGELES, CA, 90071-2899, US

(21) Appl. No.: 10/656,898

(22) Filed: Sep. 5, 2003

Related U.S. Application Data
(60) Provisional application No. 60/408,547, filed on Sep. 5, 2002.

(51) Int. Cl. H01L 29/06

(52) U.S. Cl. 257/9

(57) ABSTRACT

A nanostructure device is made up of a nanostructure, such as a single-walled carbon nanotube, spanning two electrical conductors, mounted on a substrate. A passivation layer may cover a portion of the conductors and the nanostructure. A thin polymer layer is deposited over an exposed portion of the nanotube. In this configuration, the device may perform like an n-type field effect transistor. The polymer material may be selected for interactivity with a particular chemical species or compound. The device may therefore be used as a resistive sensor that responds to the particular species or compound by exhibiting a change in resistivity.

### CROSS-REFERENCE TO RELATED APPLICATION

This application claims priority pursuant to 35 U.S.C. § 119(e) to U.S. Provisional Application Ser. No. 60/408547, filed Sep. 5, 2002, which application is specifically incorporated herein, in its entirety, by reference.

### BACKGROUND OF THE INVENTION

1. Field of the Invention

The present invention relates to nanostructure devices, such as nanotube sensors and transistors, and methods for fabricating the same.

2. Description of Related Art

Single-walled nanotube (“SWNT”) devices, including field-effect transistors (“FET's”) and resistors, can be fabricated using nanotubes grown on silicon or other substrates by chemical vapor deposition from iron-containing catalyst nanoparticles with methane/hydrogen gas mixture at 900° C. Other catalyst materials and gas mixtures can be used to grow nanotubes on substrates, and other electrode materials and nanostructure configurations and have been described previously by Gabriel et al. in U.S. patent application Ser. No. 10/099664 and in U.S. patent application Ser. No. 10/177929, both of which are incorporated by reference herein. Currently, technology for constructing practical nanostructure devices is in its infancy. While nanotube structures show promise for use as sensor devices and transistors, current technology is limited in many ways.

For example, it is known that a p-type FET may be constructed by disposing a carbon nanotube between electrodes on a silicon substrate. A device of this type naturally exhibits p-type behavior. To fully realize the potential of nanostructure FET's as nano-scale circuit devices, however, it is desirable to construct compatible nanostructure FET's that exhibit n-type behavior.

For further example, it is known that a nanotube disposed between two conductors may be operated in a resistive mode as a chemical sensor. The nanotube conducts along its outer molecular layer, so any bonding or other interaction between this outer layer and ambient chemicals may noticeably change its conductivity. The degree of change in conductivity may be proportional to the concentration of an ambient target chemical. However, the response of a nanotube sensor in many real-world chemical environments may be unpredictable. That is, the nanotube may be influenced in an unpredictable fashion by a variety of environmental chemicals. This aspect of prior-art nanotube devices limits their applicability as sensors to a few specialized applications in which the chemical environment is controlled. More practical sensors will selectively respond to certain targeted chemicals or chemical families, while being unaffected by chemicals that are not within its target parameters. It is desirable, therefore, to provide a nanotube device that exhibits a higher degree of selectivity to known targets.

### SUMMARY OF THE INVENTION

The present invention provides a novel nanotube device, and method for making the same, that overcomes the limitations of the prior art. The nanotube device exhibits qualities of an n-type FET. In addition, when operated in a resistive mode as a chemical sensor, the device can be made to respond to selected environmental chemicals in a targeted fashion.

The nanotube device comprises a nanotube, such as a carbon nanotube disposed along a substrate, such as a silicon substrate. The nanotube spans two conductive elements, which may serve as electrical terminals, or as a source and drain. A passivation layer, such as of silicon monoxide, may be deposited over the conductive elements and a portion of the nanotube, leaving a portion of the nanotube between the conductive element exposed. The nanotube may be coated with a thin polymer layer, such as poly(ethylene imine) (“PEI”). The polymer layer may be about 10 nm thick. In this configuration, the device may be operated as an n-type FET. It may also be operated in a resistive mode as a sensor, and exhibits an improved response to NH₃, NO₂, and H₂.

Instead of, or in addition to PEI, the nanotube may be coated with a variety of other polymers. The polymers may be selected for reactivity and selectivity for desired chemical targets. Thus, the nanostructure device may be adapted as a sensor for a variety of different chemicals. It is believed that similar nanostructures using nanorods or nanowires instead of nanotubes could be constructed, and would exhibit similar qualities.

A more complete understanding of the nanostructure device with polymer recognition layer will be afforded to those skilled in the art, as well as a realization of additional advantages and objects thereof, by a consideration of the following detailed description of the preferred embodiment. Reference will be made to the appended sheets of drawings which will first be described briefly.

### BRIEF DESCRIPTION OF THE DRAWINGS

FIG. 1 is a shows a schematic of an exemplary contact-passivated nanostructure device according to the invention.

FIG. 2 is an atomic force microscopy image of a device such as diagrammed in FIG. 1.

FIG. 3A shows exemplary electrical properties of a non-passivated nanotube device that is not coated with a polymer layer.

FIG. 3B shows exemplary electrical properties of a non-passivated nanotube device that is coated with a PEI layer.

FIG. 4A shows exemplary electrical properties of a passivated nanotube device that is not coated with a polymer layer.

FIG. 4B shows exemplary electrical properties of a passivated nanotube device that is coated with a PEI layer.

FIG. 5A shows exemplary response of a nanotube device that is not coated with a polymer layer to fluctuating levels of NH₃ in a test environment.

FIG. 5B shows exemplary improved response of a nanotube device coated with a PEI layer to NH₃ in the same test environment.

FIG. 6 shows exemplary response of a nanotube device coated with a PEI layer to fluctuating levels of H₂ in a test environment.

### DETAILED DESCRIPTION OF THE PREFERRED EMBODIMENT

The present invention provides a nanostructure sensor that includes a polymer functionalization layer, also referred to as a recognition layer. The device with a functionalization layer exhibits properties of an n-type FET. The device may be used as a chemical sensor with improved responsiveness to selected chemicals. In the detailed description that follows, like element numerals are used to denote like elements appearing in one or more of the figures.

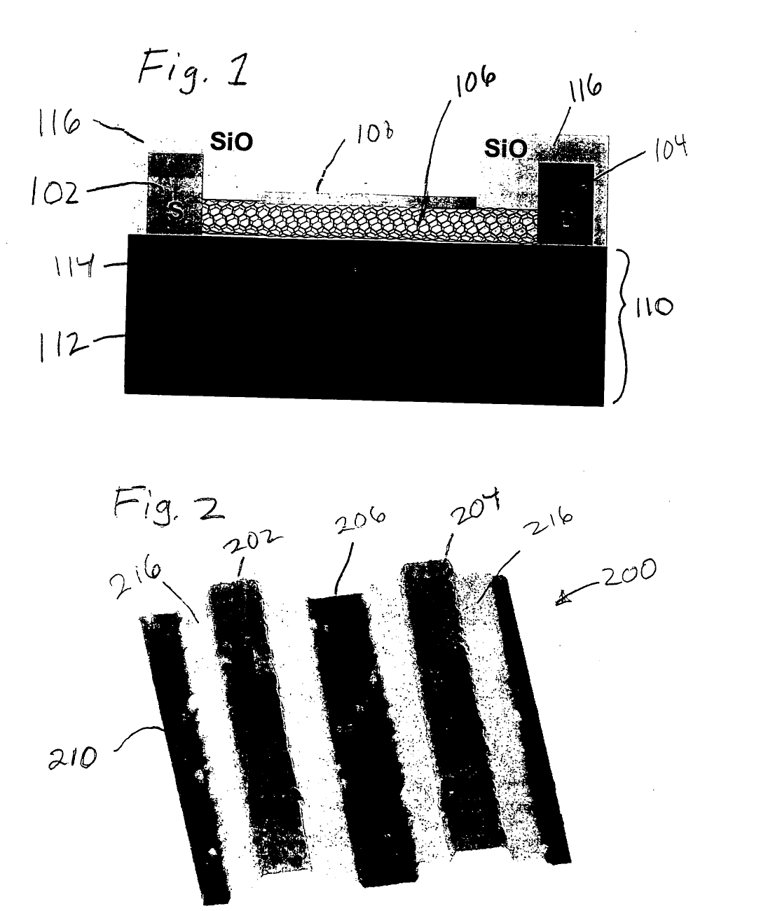

A schematic of a nanostructure device 100 with a coated polymer recognition layer is shown in FIG. 1. Device 100 may be used as a contact-passivated SWNT FET, or as sensor in a resistive mode. Device 100 comprises electrodes 102, 104 in electrical contact with one or more nanotubes 106 spanning the electrodes. The electrodes 102, 104 can be made from any conductive material. For example, in an embodiment of the invention, electrodes 102, 104 were patterned from titanium films about 35 nm thick capped with gold layers about 5 nm thick, with a gap of about 0.75 μm between source 102 and drain 104. Nanotube 106 is a single-walled nanotube structure, of carbon, germanium, or any other suitable material. The assembly of all the foregoing elements are supported by substrate 110 comprising a silicon back gate 112 and a silicon dioxide layer 114. Any other suitable substrate may be used. The electrodes and portions of the nanotubes closest to the electrodes may optionally be covered with a passivation layer 116, for example, silicon monoxide about 70 nm thick. Other passivation materials that are electrically insulating and at least somewhat impermeable can be used. If a passivation layer is used, a portion of the nanotube between the electrodes is left uncovered by the passivation layer.

Metal layers and passivation layers can be formed by evaporation, sputtering, chemical vapor deposition processes, or any other method known in the thin film arts. Methods for fabricating nanotubes are known in the art, for example, as disclosed in the references cited herein.

Device 100 additionally includes a polymer layer 108, sometimes referred to as a recognition layer in a sensor context, or more generally, as a functionalization layer. Various different polymer materials may be selected for use in polymer layer 108, some examples of which are provided later in the specification. The polymer layer 108 may be applied to the nanotube 106 using any suitable method. For example, in an embodiment of the invention, the substrate 110, electrodes 102, 104 and nanotube 106 were submerged in a solution of poly(ethylene imine) (PEI, average molecular weight −25,000, Aldrich) at about 20% by weight in methanol. After soaking overnight, they were removed and rinsed with methanol. A thin layer, such as less than 10 nm of PEI coated the exposed portion of nanotube 106 after rinsing. Other suitable polymers, or combinations of polymers, may be substituted for PEI. Other solvents and rinse agents may also be suitable.

FIG. 2 is an image of an exemplary nanotube device 200 according to the schematic shown in FIG. 1, including passivation and PEI layers. The image was generated by atomic force microscopy, and the image size is 2.75 μm. The nanotube 206 is colored for clarity. Also visible are the substrate 210 and the passivation layer 216 covering the two conductive elements 202 and 204. Apparent non-uniformities in the thickness of the PEI layer appear along the length of the nanotube 206.

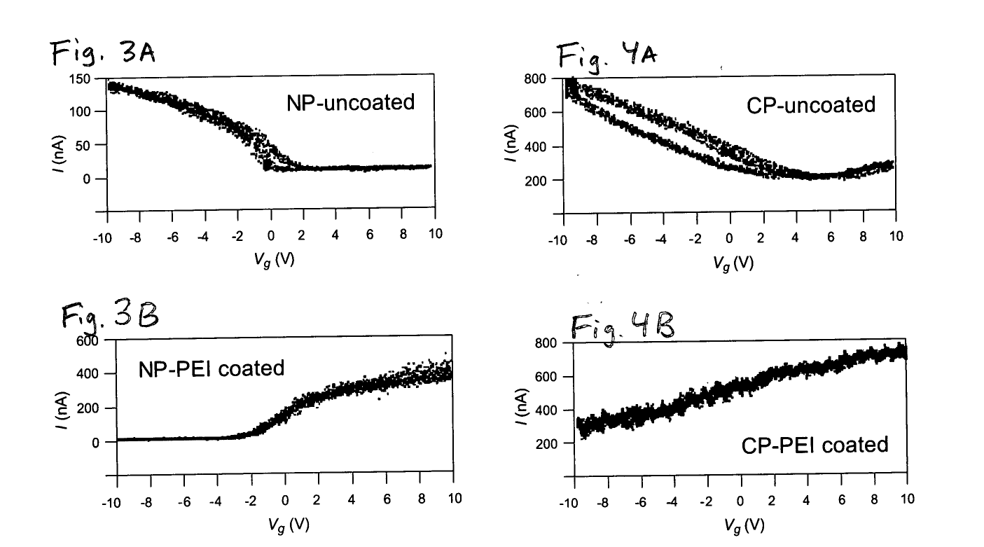

The effect of the additional polymer layer is illustrated by FIGS. 3A-B and 4A-B. Electrical current (I) is shown on the vertical axis of these graphs, and gate voltage (V_{g}) on the horizontal axis. FIG. 3A shows the electrical characteristics of an unpassivated nanotube device (i.e., one lacking passivation layer 116) before PEI coating. Prior to PEI coating, the as-made semiconducting SWNT exhibits p-type FET characteristics. After addition of the PEI layer 108, the device exhibits properties of a n-type FET.

Similar results were achieved for a device that included a passivation layer 116. The similar change in electrical characteristics of the contact-passivated device is clear from comparison of FIGS. 4A and 4B. FIG. 4A shows the p-type behavior of the uncoated contact-passivated device, as revealed by the decreasing conductance of the device as the gate voltage increases. FIG. 4B shows that after PEI adsorption, the SWNT exhibits clear n-type FET characteristics. The conductance- of the device increases with increase of V_{g}.

Notably, both unpassivated and contact-passivated SWNT devices show this difference in behavior after functionalization with PEI, whether operated in air, or in vacuum. Similar comparisons may be drawn for operation in air as in vacuum, with the difference that in general, hysterisis in the I-V_{g} curve is significantly larger in air.

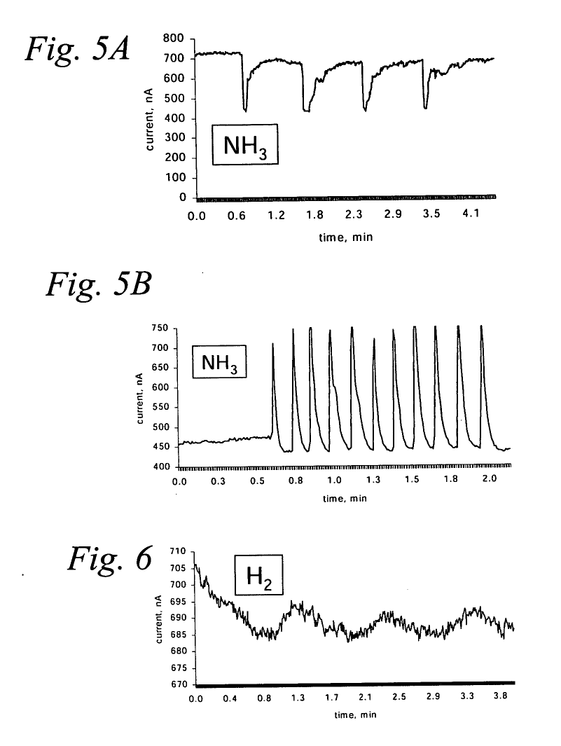

Surprisingly, functionalization of nanostructure devices by coating with PEI has been found to improve the response of the devices for some gases, such as NH₃ and NO₂, and induce a response to other gases, such as H₂. Gas sensor behavior of the non-functionalized and the PEI functionalized semiconducting nanostructure devices are shown in FIGS. 5A and 5B, respectively. The response and recovery of the PEI-functionalized ammonia sensor (FIG. 5B) are remarkably fast. The response to ammonia is also dependent on a gate voltage. At positive gate, measured current through the PEI-functionalized device is increasing significantly. Upon exposure to pure ammonia gas the current increases from 400 nA to 800 nA (FIG. 3B). The measured change in current is dependent on ammonia concentration. When the device was exposed to different concentrations of ammonia in argon, a change in the device conductivity was found to be proportional to ammonia concentration.

In absence of a recognition layer, SWNT FET devices seem to have no response to hydrogen. PEI coating on both non-passivated and contact-passivated devices induces the sensing for hydrogen gas. The changes in conductivity of a PEI-coated, contact-passivated device are shown in FIG. 6. Response to fluctuating levels of hydrogen is plainly apparent.

These principles are applicable to SWNT FET devices that contain one nanostructure, or a plurality of nanostructures, as the sensing element. Before functionalization, the nanostructures can be in contact with the substrate 110 surface, in contact with an intervening layer between the substrate surface and the nanostructures, or can be suspended over the substrate surface.

Other polymers that may be used to effect a conductivity change in nanotubes in response to absorption of target species include:
poly(4-vinylphenol)
poly(styrene-co-allyl alcohol), 5.7% hydroxyl
poly(a-methylstyrene)
poly(vinyl chloride-co-vinyl acetate), 10% vinyl acetate
poly(vinyl acetate)
poly(N-vinylpyrrolidone)
poly(carbonate bisphenol A)
poly(styrene)
poly(styrene-co-maleic anhydride), 50% styrene
poly(sulfone)
poly(methyl methacrylate)
poly(methyl vinyl ether-co-maleic anhydride)
poly(vinyl butyral)
poly(vinylidene chloride-co-acrylonitrile), 80% vinylidene chloride
poly(caprolactone)
poly(entylene-co-vinyl acetate), 82% ethylene
poly(ethylene oxide)

Detailed descriptions of the chemical sensitivity of these polymer materials can

be found in the following three references, which are incorporated by reference herein:

1) Taylor, R. F.; Schoultz, J. S. Handbook of Chemical and Biological Sensors, IOP Publishing Ltd 1996.

2) Albert, K. J.; Lewis, N. S.; Schauer, C. L.; Sotzing, G. A.; Stitzel, S. E.; Vaid, T. P.; Walt, D. R. Chem. Rev. 2000, 100, 2595-2626.

3) Lonergan, M. C.; Severin, E. J.; Doleman, B. J.; Beaber, S. A.; Grubbs, R. H.; Lewis, N. S. Chem. Mater. 1996, 8, 2298-2312.

Polymers such as the foregoing may be dissolved and coated on nanostructures in a manner similar to that described for PEI above. Other polymer materials than those listed above may also be useful. It is believed that the polymer layer acts to cause a selective response by the nanostructure to target species that are selectively absorbed or otherwise interacted with by the polymer layer on the nanostructure. However, the precise functioning of the nanostructure device as a sensor is not well understood, and the invention is not limited by the foregoing hypothesis. If true, the hypothesis suggests that a nanostructure sensor may be made to respond selectively to a particular material, by coating it with a polymer having a known selective affinity for the desired target. Also, more than one material may be included in a target group by combining polymers with different affinities. The polymer layer may be modified to produce different effects. For example, part of the nanotube or other nanostructure could be masked during a coating process for the polymer layer. After the polymer layer is applied, the masking layer could be stripped away, leaving a discontinuous polymer layer on the nanotube. Using a similar process, different polymers could be deposited at different places along a nanostructure.

Having thus described a preferred embodiment of the nanostructure device with a polymer functionalization layer, it should be apparent to those skilled in the art that certain advantages of the within system have been achieved. It should also be appreciated that various modifications, adaptations, and alternative embodiments thereof may be made within the scope and spirit of the present invention. For example, a nanotube device has been illustrated, but it should be apparent that the inventive concepts described above would be equally applicable to devices that incorporate other nanostructures, such as nanorods, nanofibers or nanowires. The invention is defined by the following claims.

1. A nanostructure sensor for sensing a target species, comprising:
at least one nanostructure;
at least two conducting elements in electrical communication with the at least one nanostructure;
a polymer layer on the at least one nanostructure.

2. The nanostructure sensor of claim 1, wherein the at least one nanostructure is selected from the group consisting of nanotubes, nanowires, nanofibers, and nanorods.

3. The nanostructure sensor of claim 1, wherein the at least one nanostructure comprises a single-wall carbon nanotube.

4. The nanostructure sensor of claim 1, wherein the at least two conducting elements comprise metal electrodes.

5. The nanostructure sensor of claim 1, wherein the at least two conducting elements are in direct physical contact with the at least one nanostructure.

6. The nanostructure sensor of claim 1, wherein the polymer layer is selected to interact with the target species.

7. The nanostructure sensor of claim 1, wherein the polymer layer on the at least one nanostructure is discontinuous.

8. The nanostructure sensor of claim 1, wherein the polymer layer comprises more than one material.

9. The nanostructure sensor of claim 1, wherein the target species comprises ammonia and the polymer layer is PEI.

10. The nanostructure sensor of claim 1, wherein the particular species comprises hydrogen and the polymer layer is PEI.

11. The nanostructure sensor of claim 1, further comprising a gate electrode.

12. The nanostructure sensor of claim 1, further comprising passivation material covering regions in which there is electrical communication between the at least two conduction elements and the at least one nanostructure.

13. A method of making a nanostructure sensor for sensing target species, comprising:
providing at least one nanostructure;
making electrical contact to the at least one nanostructure with at least two conducting elements;
coating the at least one nanostructure with a polymer selected to interact with the target species.

14. The method of claim 13, further comprising covering regions where the at least two conducting elements make contact to the at least one nanostructure with a passivation material.

15. The method of claim 13, further comprising providing a gate electrode.

16. A method of sensing target species, comprising:
providing at least one nanostructure;
making electrical contact to the at least one nanostructure with at least two conducting elements;
coating the at least one nanostructure with a polymer that interacts with the target species and, in response to the interaction, effects a change in the at least one nanostructure that can be measured electrically;
measuring an electrical signal from the at least one nanostructure; and
correlating the electrical signal to sensing of the target species.

17. The method of claim 16, further comprising providing a passivation material to cover regions where the at least two conducting elements make electrical contact to the at least one nanostructure.

18. The method of claim 16, further comprising providing a gate electrode.
